(19) United States
(12) Patent Application Publication
(10) Pub. No.: US 2009/0217863 A1
(43) Pub. Date: Sep. 3, 2009

(54) METHOD OF INDICATING THE PRESENCE OF A HAZARDOUS SUBSTANCE AND STICKER THEREFOR

(76) Inventors: Natan Muskal, Moshav Ganot (IL); Raanan Novik, Rehovot (IL)

Correspondence Address: YORAM TSIVION, P.O. BOX 1307, PARDES HANNA, 37111, IL

(21) Appl. No.: 12/295,730

(22) PCT Filed: Feb. 5, 2007
(86) PCT No.: PCT/IL2007/000146

§ 371 Date: Oct. 2, 2008

(30) Foreign Application Priority Data
Apr. 2, 2006 (IL) 174717

(51) Int. Cl. G01D 21/00

(52) U.S. Cl. 116/206

(57) ABSTRACT

A sticker for indicating the presence of hazardous substances on a component comprising a see-through layer having an outer surface and an inner surface; an indicator layer attached to the inner surface and having an indicator/reagent for providing a visible indication of the hazardous substance; and an adhesive located on the inner surface and/or on the indicator layer for attaching the sticker to the component.

### FIELD OF INVENTION

The present invention relates to indicators for indicating the presence of materials, in particular the presence of hazardous substances.

### BACKGROUND OF THE INVENTION

Due to environmental, health and safety concerns, there is a need to discover the presence of hazardous substances on devices, such as electronic components. Due to such concerns, directives have been issued (e.g. RoHS—Restriction of Hazardous Materials; EU Directive 2002/95/EC) restricting electronic equipment from containing certain hazardous substances. These substances include lead; mercury; cadmium; hexavalent chromium; polybrominated biphenyl compounds (PCB) and polybrominated biphenyl ether compounds (PBDE).

The presence of such hazardous materials can occur for a number of reasons including contamination due to dual use of a production line (i.e. where one of the production lines uses one or more hazardous substance); or contamination from the manufacturing environment in general, the use of such materials in the manufacturing process, and the like. The RoHS directive requires electronic equipment manufacturers to validate that their products do not contain the restricted substances.

Presently, X-ray fluorescence and wet chemical application are generally used to check for the presence of the afore-mentioned substances on electronic components. X-ray fluorescence is typically: expensive; requires (skilled) technicians; uses X-ray radiation, which can be a safety concern; is time consuming unless merely “sample checking” (e.g. every tenth component) is used; and requires the producing of some sort of paperwork to provide a physical and lasting documentation of the results.

Wet chemical application may leave a residue on the component and is not readily suited for mass production (i.e. is also time consuming unless merely “sample-checking” is used). U.S. Pat. No. 6,248,593 (Esswein, et al) provides a version of wet chemical application wherein a handwipe is used to collect lead contamination on surfaces and the lead, if any, is solubilized with an aqueous acid solution and treated with rhodizonate or sulfide anions which produce a characteristic color in the presence of lead.

### SUMMARY OF THE INVENTION

The present invention relates to a patch or sticker capable of indicating the presence of hazardous materials—in particular on electronic components and the like; and a method for providing an indication of the presence of a hazardous substance.

The indication of the presence of the hazardous material provided by the sticker and method is essentially a permanent indication—the sticker is designed to stay on the electronic component.

Although the invention is particularly suited for use with electronic components, it may be used in a variety of other settings such as on a painted wall (e.g. to test for the presence of lead, etc), in the field of produce and foodstuffs, and so on.

As such the term “component” or “components” will be used in the specification and claims to denote any item to be tested for the presence of hazardous materials.

The term “electronic component” will be used herein the specification and claims in its broadest connotation and may include any electronic equipment (computers, terminals, DVDs, stereos, televisions, electronic games, etc.) and/or elements thereof, for example printed circuit boards, integrated circuits, etc and their packaging.

The sticker of the present invention comprises: a see-through layer having an outer surface and an inner surface; an indicator layer comprising an indicator/reagent for providing a visible indication of the presence of the hazardous substances and being attached to the inner surface of the see-through layer; and an adhesive located on at least a portion of the inner surface of the see-through layer and/or on at least a portion of the indicator layer for facilitating attaching the sticker to the component.

The term “see-through layer” should be understood to mean that the layer is “transparent”; or “translucent” to the extent that an indication by the indicator/reagent is visible therethrough.

The method of providing an indication of the presence of a hazardous substance of the present invention comprises: providing the afore-mentioned sticker; applying a small amount of an extracting solution (solubilizing the hazardous material or an element thereof) at a location on a component; and sticking the sticker on that location.

As the sticker itself may be adapted to comprise extracting solution, the applying of the extracting solution, in certain embodiments, may be accomplished at the time when the sticker is stuck on the component.

According to a particular embodiment of the invention, the sticker (typically the indicator layer) may further comprise the extracting solution, for example in a side by side arrangement, one on top of the other or other appropriate configuration.

According to another embodiment of the invention, the sticker further comprises a liner or support layer running along the side of the sticker that is intended for application on the component(s), i.e. the underside of the sticker. The liner is particularly useful for holding, carrying, packaging and facilitating storage of a plurality of stickers.

According to yet another embodiment of the invention, the sticker comprises a plurality of indicator agents, which may be disposed in separate locations (e.g. in separate compartments) to help identify the particular hazardous material or materials present, if any.

### BRIEF DESCRIPTION OF THE DRAWINGS

The invention may be more clearly understood upon reading of the following detailed description of non-limiting exemplary embodiments thereof, with reference to the following drawings, in which:

FIG. 1 is a bottom view of an embodiment of a sticker of the present invention;

FIG. 2 is a side sectional view along line II-II of FIG. 1;

FIG. 3 shows the sticker of FIG. 1 attached to an electronic component;

FIG. 4 is a side sectional view showing another embodiment of the present invention;

FIG. 5 is a side sectional view of a plurality of stickers of the present invention further comprising a liner for carrying same; and

FIG. 6 is a top view of another embodiment of the present invention wherein the sticker comprises a plurality of separately disposed indicator agents.

### DETAILED DESCRIPTION OF THE INVENTION

For clarity, throughout the description, similar or analogous parts will be referred to using the same reference numerals.

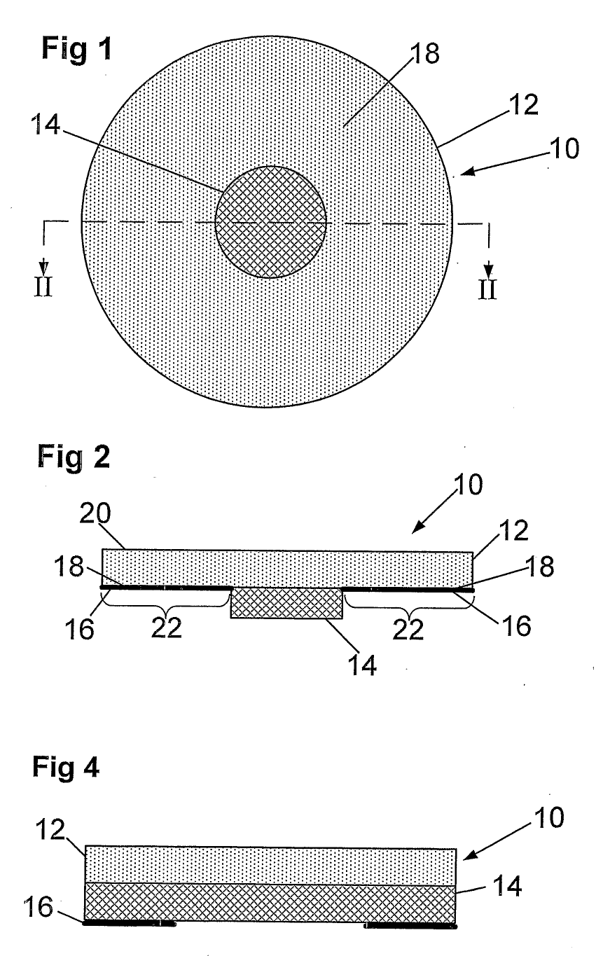

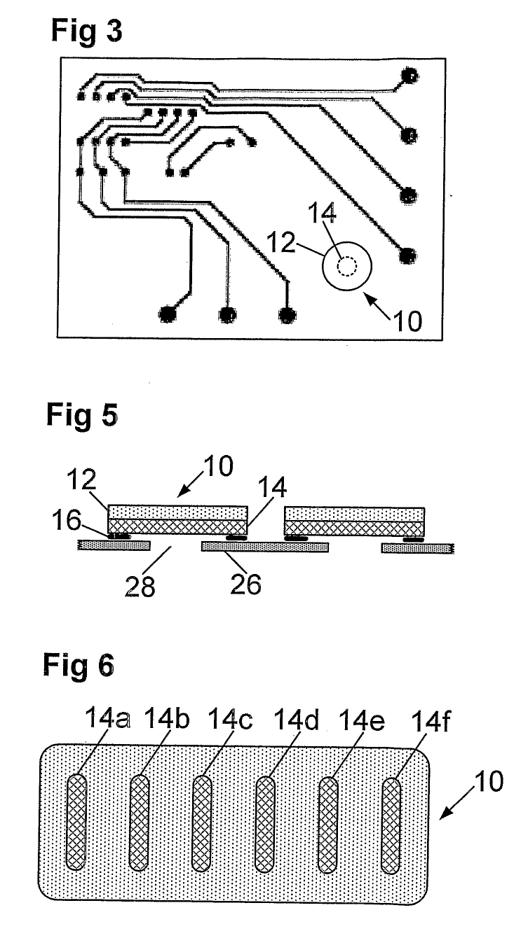

Referring first to FIGS. 1-3, there is shown a sticker 10 of the present invention comprising a see-through layer 12, an indicator layer 14 and an adhesive 16.

The see-through layer 12 has an inner surface 18 and an outer surface 20. The indicator layer 14 is attached (e.g. by an adhesive, which could be adhesive 16) to the inner surface 18 of the see-through layer 12, for example at a central region thereof such that there are margins 22 (annularly shaped in the case of a circular sticker) with an adhesive (e.g. the same adhesive 16) thereat for allowing good contact between the sticker 10 and an electronic component, for example printed circuit board (PCB) 24 to be tested for the presence of a hazardous substance (not seen).

The see-through layer 12 is typically made of a polymeric material, for example a polyamide, and is transparent or at least translucent such that a positive indication, if any, can be discerned through the see-through layer. The see-through layer 12 is preferably heat and chemical resistant—as may be any or all elements of the sticker 10.

The indicator layer 14 may be for example a porous layer and an indicator or reagent (not seen) is located in the pores. Other variations, for example, can include wherein the layer 14 is in the form of an indicator gel, liquid, solid (e.g. powder or dried solution), capsules—or combination thereof. Further, the indicator can be incorporated or associated with the adhesive 16 in which case there may be in effect no need for a separate indicator layer.

FIG. 4 shows an example of another embodiment of the present invention, wherein the sticker 10 comprises an indicator layer 14 that extends to about the edge of the sticker. In this case, the adhesive 16 is located at the underneath surface of the indicator layer 14, typically at the periphery thereof.

Prior to applying the sticker 10 to the PCB 24 typically a small amount of extracting solution (e.g. a weak acid solution, not shown) is applied at a location on the surface of the electronic component and then the sticker is placed at that location.

Alternatively, the extracting solution can be applied to any portion of the sticker 10 intended for contacting the PCB 24; and then the sticker is applied to thereto.

Alternatively, the sticker 10 itself may be adapted to comprise extracting solution and so merely sticking the sticker on the PCB 24 accomplishes the act of applying the extracting solution to thereto.

If there is a need for storing the sticker 10 for any length of time, a removable protective layer (not shown) may be included for covering and protecting the portion of the sticker intended for being in contact with the PCB 24. In this regard, the sticker 10 may also comprise a protective wrapping, for example, to protect it—particularly the indicator layer—from environmental factors such as radiation (e.g. sunlight), dirt and the like.

As an example only, the indicator or reagent disposed in the indicator layer 14 can be a rhidozonate or sulfide ions whereby the presence of lead, Pb, can be determined by a color change as seen via the see-through layer 18. As should be understood, many other indicators can be used whereby the presence of hazardous substances such as mercury, cadmium, hexavalent chromium, polybrominated biphenyl compounds and polybrominated biphenyl ether compounds may also be determined.

Examples of additional indicators include: 1,5-diphenylthiocarbazone; 1,5-diphenyl carbohydrazide; 4-(2-pyridylazo)resorcinol; diphenylcarbazone; cuprous iodide; p-dimethylaminobenzylidenerhodanine; and 1,5-diphenylcarbazone—as well as fluorescein, p-aminophenol and 4,4′-bis-(dimethylamino)-thiobenzophenone which can be used to detect the presence of bromine and bromides such as hydrobromic acid that can be used to help ascertain the presence of the above-mentioned Br-containing hazardous substances.

It should be further understood that determining the presence of such hazardous materials may actually be accomplished by determining the presence of a related chemical, valence, ionic form, etc. of the substance; and furthermore, that the hazardous substance may be present in the component in a variety of chemical, valence, ionic forms, etc. Moreover, in the specification and claims it should be understood that mention of the substances in any one chemical, valence, ionic form etc. includes reference to all such forms—including relevant precursors which may react to form hazardous materials.

Thus, the sticker and method of the present invention provide for determining the presence of a hazardous substance and, very importantly, for the continuous indication thereof. In other words, the sticker 10 (unless removed or tampered with) provides a permanent indication of the presence of a particular hazardous substance as it is designed to remain on the PCB 24.

FIG. 5 shows an embodiment of the present invention wherein the sticker 10 has associated with it a liner or support layer 26 running along the underside of the sticker 10—i.e. the side of the sticker intended for applying on the surface of the component (e.g. PCB 24). The liner 26 is particularly useful for holding, carrying, packaging and facilitating storage of a plurality of stickers 10 (two shown in FIG. 5). For such purpose the liner 26 is may be in the form of an extended strip, or it may be square, rectangular, circular, etc. to carry an array of stickers 10. The liner 26 may completely cover the bottom of the sticker 10 (preferably at least the adhesive 16), and the sticker would be peeled from the liner prior to sticking on the PCB 24. Alternatively, the liner 26 may comprise openings 28 aligned with the indicator layers 14 to facilitate wetting the indicator layer with indicator solution prior to peeling off the liner and applying the sticker 10 to the PCB 24.

FIG. 6 shows the sticker 10 comprising a plurality of different indicator agents disposed in a plurality of separate indicator layers 14a, 14b, 14c, 14d, 14e and 14f. With such an arrangement, the sticker 10 may more easily indicate which hazardous substance or substances are present, if any. The liner 26 used with this embodiment may comprise a plurality of openings 28 (not seen), aligned with the indicator layers 14a, 14b, 14c, 14d, 14e and 14f.

Also important to note is that the sticker and method of the present invention are compatible with use in the mass production of electronic components. During the production, typically at the end of the manufacturing stage, a machine, device or worker can easily be allotted the task of placing a small amount of extracting solution on a predetermined location on the electronic components such as PCBs 24 (or on the underneath portion of the sticker 10) and sticking the sticker 10 on that location. It should be understood that such a machine can be retrofitted into existing production lines.

It should be understood that there are various stickers and methods for providing an indication of the presence of hazardous materials that can be devised according to the present invention and that the above description is merely explanatory. Thus, the present sticker and method can be embodied in a variety of aspects falling within the scope of the present invention, mutatis mutandis.

1. A sticker for indicating the presence of hazardous substances on a component, said sticker comprising:
a see-through layer having an outer surface and an inner surface;
an indicator layer comprising an indicator/reagent for providing a visible indication of the presence of said hazardous substances and being attached to the inner surface of said see-through layer; and
an adhesive located on at least a portion of the inner surface of said see-through layer and/or on at least a portion of said indicator layer for facilitating attaching said sticker to said component.

2. The sticker according to claim 1, wherein the adhesive is adapted to ensure that said sticker remains on the component to provide an essentially permanent indication of the presence, or absence, of the hazardous substance.

3. The sticker according to claim 1, wherein any one or all of the see-through layer, the indicator layer and the adhesive is heat and/or chemical resistant.

4. The sticker according to claim 1, wherein the see-through layer comprises a polymeric material.

5. The sticker according to claim 1, wherein it comprises an extracting solution for solubilizing the hazardous material or an element thereof.

6. The sticker according to claim 1, wherein the indicator layer comprises, or is in the form of, any one of a gel, a liquid, a solid, capsules or combination thereof.

7. The sticker according to claim 1, wherein the indicator layer is a porous layer.

8. The sticker according to claim 1, wherein the adhesive is incorporated or associated with the indicator layer.

9. The sticker according to claim 1, wherein the indicator/reagent contains one of rhidozonate and sulfide ions; 1,5-diphenylthiocarbazone; 1,5-diphenyl carbohydrazide; 4-(2-pyridylazo)resorcinol; diphenylcarbazone; cuprous iodide; p-dimethylaminobenzylidenerhodanine; 1,5-diphenylcarbazone; fluorescein; p-aminophenol; and 4,4′-bis-(dimethylamino)-thiobenzophenone.

10. The sticker according to claim 1, wherein the indicator layer has an area smaller than said see-through layer.

11. The sticker according to claim 1, wherein it further comprises a removable protective layer or wrapping for covering and protecting any portion thereof.

12. The sticker according to claim 1, wherein the hazardous substances are at least any one of lead, mercury, cadmium, hexavalent chromium, polybrominated biphenyl compounds and polybrominated biphenyl ether compounds; and bromine and bromides, including related chemical, valence and ionic forms; and relevant precursors.

13. The sticker according to claim 1, further having associated therewith a liner at the underside thereof.

14. The sticker according to claim 13, wherein the liner comprises an opening aligned with the indicator layer.

15. The sticker according to claim 1, wherein the indicator layer is constituted by a plurality of separately disposed indicators.

16. The sticker according to claim 15, wherein the indicators reside in compartments having a different indicator in each compartment.

17. A method of providing an indication of the presence of a hazardous substance on a component, comprising:
(a) providing a sticker as defined in any one of the preceding claims;
(b) applying a small amount of an extracting solution at a location on said component or on the indicating layer of the sticker; and
(c) sticking said sticker on said location.

18. The method according to claim 17, wherein applying the extracting solution is performed by sticking said sticker on the component so that steps (b) and (c) are essentially performed simultaneously.

19. The method according to claim 17, further comprising allowing the sticker to remain on the component in order to provide a continuous indication as to the presence of the hazardous material.

20. The method according to claim 17, wherein sticking the sticker at a location on the component comprises sticking the sticker during production of said component.

16. The sticker according to any one of the preceding claims, wherein the indicator layer is constituted by a plurality of separately disposed indicators

17. The sticker according to claim 16, wherein the indicators reside in compartments having a different indicator in each compartment.

18. A method of providing an indication of the presence of a hazardous substance on a component, comprising: (a) providing a sticker as defined in any one of the preceding claims; (b) applying a small amount of an extracting solution at a location on said component or on the indicating layer of the sticker; and (c) sticking said sticker on said location.

19. The method according to claim 18, wherein applying the extracting solution is performed by sticking said sticker on the component so that steps (b) and (c) are essentially performed simultaneously.

20. The method according to claim 18, further comprising allowing the sticker to remain on the component in order to provide a continuous indication as to the presence of the hazardous material.

21. The method according to any one of claims 18-20, wherein sticking the sticker at a location on the component comprises sticking the sticker during production of said component.
